(19) United States
(12) Patent Application Publication
(10) Pub. No.: US 2010/0193747 A1
(43) Pub. Date: Aug. 5, 2010

(54) PROCESS OF PREPARING CARBON NANOTUBE FILM, THE CARBON NANOTUBE FILM PREPARED THEREBY AND CARBON NANOTUBE ELEMENTS COMPRISING THE SAME

(75) Inventors: Hisashi Kajiura, Shanghai (CN); Yongming Li, Beijing (CN); Hongliang Zhang, Beijing (CN); Yunqi Liu, Beijing (CN); Lingchao Cao, Beijing (CN); Dacheng Wei, Beijing (CN); Yu Wang, Beijing (CN); Liping Huang, Beijing (CN)

Correspondence Address: K&L Gates LLP, P. O. BOX 1135, CHICAGO, IL, 60690, US

(73) Assignee: SONY CORPORATION, Tokyo (JP)

(21) Appl. No.: 12/638,452

(22) Filed: Dec. 15, 2009

(30) Foreign Application Priority Data
Dec. 15, 2008 (CN) 200810182994.8

(51) Int. Cl. H01B 1/04; C23C 16/44

(52) U.S. Cl. 252/502; 427/249.1; 977/742; 977/843; 977/750

(57) ABSTRACT

A process of a preparing transparent conductive carbon nanotube (CNT) film, the carbon nanotube film prepared by the process, and carbon nanotube elements including the carbon nanotube film are provided. The carbon nanotube film has a higher transparency and much lower sheet resistance compared with the carbon nanotube film obtained by a conventional filtration process.

### CROSS REFERENCES TO RELATED APPLICATIONS

The present application claims priority to Chinese Priority Patent Application CN 200810182994.8 filed in the Chinese Patent Office on Dec. 15, 2008, the entire content of which is hereby incorporated by reference.

### BACKGROUND

The present application relates to a process of preparing a carbon nanotube(CNT) film, specifically a process of preparing a transparent conductive carbon nanotube film, and the CNT film prepared by the process. The present application also relates to a carbon nanotube element comprising the prepared carbon nanotube films.

As one-dimensional nanomaterials, carbon nanotubes (CNTs) have increasingly become the focus of multidisciplinary study and present many new opportunities for fundamental sciences and new technologies, due to their unique mechanical and chemical properties and their prospects for practical applications. CNTs combine strength and flexibility, so they are excellent candidates for flexible electronic components. Recently, the flexible transparent conductive films made of CNTs have drawn much attention, and has become the focus of interests at present, partly because of their applications in electroluminescence, photoconductor and photovoltaic devices.

Although the optically transparent and highly conductive indium tin oxide (ITO) has enjoyed widespread use in optoelectronic applications, the inherent brittleness of ITO severely limits the film flexibility. The CNT thin films are suitable to replace ITO due to their properties as below. For instance, CNT films can be repeatedly bent without fracture. The thin films with low sheet resistance are also transparent in the visible and infrared range. Furthermore, both the low cost and tunable electronic properties offer additional advantages to CNT thin films.

In the practical applications of carbon nanotube films, it is necessary to consider both the transparency and the conductivity of the carbon nanotube film. The increase in thickness of a carbon nanotube film will enhance the conductivity of the film, but decrease the transparency of the film, and vice versa.

In the prior art, the carbon nanotube film is conventionally prepared by a filtration method (see, Wu, Z, et al., A. G. Science 2004, 305, 1273) or a spray method (see, Geng, H.-Z et al., J. Am. Chem. Soc. 2007, 129, 7758).

In general, after carbon nanotubes are made by, for example, chemical vapor deposition(CVD), arc process, and the like, a carbon nanotube film is made by dispersing the carbon nanotubes in solvents, followed by filtration. The process for preparing carbon nanotube films based on filtration, however, needs much surfactant and a membrane filter. Furthermore, it takes much time to remove the membrane filter, and much “detergent” (for example, acetone) are needed during the dipping step. If the membrane filter cannot be removed completely, it will increase the sheet resistance of the CNT films, and decrease their transparency.

During the preparation of the carbon nanotube film by a spray method, the surfactant is also required to disperse carbon nanotubes into little bundles.

Moreover, when the carbon nanotubes are dispersed by ultrasonic, the ultrasonic will harm the sidewalls of the carbon nanotubes. Furthermore, the residue surfactant on the carbon nanotubes will cause stable dispersion through random adsorption on the carbon nanotubes, and will cover or denaturalize the carbon nanotubes.

Therefore, there is a desire for a process to obtain a carbon nanotube film with high conductivity and high transparency.

### SUMMARY

In an embodiment, the present application provides a process of preparing a transparent conductive carbon nanotube film, comprising:

preparing a uniform catalyst layer on a substate; and

growing the transparent conductive carbon nanotube film on the uniform catalyst layer by a chemical vapor deposition(CVD) method.

In an embodiment preparing the uniform catalyst layer includes: formulating a catalyst solution by using a solvent, forming a uniform catalyst solution film on a substrate, and drying the obtained uniform catalyst solution film, to form the uniform catalyst layer. In an embodiment, the uniform catalyst solution film has a wet-film thickness of 11 micron to 33 micron. In an embodiment, the solvent is selected from the group consisting of an alcohol based solvent, an ether based solvent and a ketone based solvent. For example, the solvent includes any one of methanol, ethanol, acetone, diethyl ether and glycerol.

In one embodiment, the CVD method includes reducing the catalyst in the catalyst layer. In an embodiment, the CVD method further includes growing a transparent conductive carbon nanotube film by using a carbon source and a carrier gas.

In an embodiment the transparent conductive carbon nanotube film grows in the CVD method at a temperature of 600° C. to 1200° C., preferably, at a temperature of 900° C. to 1000° C.

In an embodiment, the catalyst is reduced in the CVD method at a temperature of 600° C. to 1200° C., preferably, at a temperature of 900° C. to 1000° C.

In an embodiment, the catalyst is reduced by using hydrogen at 20 sccm to 2000 sccm.

In an embodiment, the catalyst is reduced for 5 minutes to 200 minutes, preferably, 10 minutes to 40 minutes.

In an embodiment, the ratio of the flow rate of the carbon source to that of the carrier gas is 1:8 to 3:4.

In an embodiment, the catalyst is selected from the group consisting of transition metals, salts of transition metals, and the combinations thereof. In another embodiment, the catalyst is selected from the group consisting of iron salts, copper salts, cobalt salts, molybdenum salts, and the combinations thereof.

In an embodiment, the catalyst is selected from the group consisting of FeCl₃, CuCl₂, and Co/Mo catalyst. In an embodiment, as for a catalyst solution, preferably, the catalyst solution has a concentration of 0.03 wt % to 2 wt %, when the catalyst is FeCl₃ or CuCl₂, or the catalyst solution has a concentration of 0.001 wt % to 2 wt %, when the catalyst is Co/Mo catalyst.

In an embodiment, the substrate used may be a quartz substrate, a silicone substrate and a glass substrate. In the present application, the transparent quartz substrate is preferred.

In another embodiment, the present application provides a carbon nanotube film.

In yet another embodiment, the present application provides a carbon nanotube element including a carbon nanotube film. In an embodiment, the carbon nanotube element is preferably selected from the group consisting of a conductive film of carbon nanotubes, a field emission source, a transistor, a conductive wire, a nano-electro-mechanic system, a spin conduction device, a nano cantilever, a quantum computing device, a lighting emitting diode, a solar cell, a surface-conduction electron-emitter display, a filter, a drug delivery system, a thermal conductive material, a nano nozzle, an energy storage system, a space elevator, a fuel cell, a sensor and a catalyst carrier.

In an embodiment, the carbon nanotube film is single-walled carbon nanotube film.

Additional features and advantages are described herein, and will be apparent from the following Detailed Description and the figures.

### BRIEF DESCRIPTION OF THE FIGURES

FIG. 1 is a schematic view of the CVD system according to an embodiment.

FIG. 2 is a schematic view of preparing a uniform catalyst solution film in an embodiment of the present application.

FIG. 3 is the SEM images of the carbon nanotube film prepared in Example 1, wherein the amplification factor in FIGS. 3(a), (b) and (c) is 2000, 8000 and 18000, respectively.

FIG. 4 is an optical image comparing the transparency of the substrate with carbon nanotube films prepared in Example 1 with the transparency of the substrate without carbon nanotube films.

FIG. 5 is an AFM image of the carbon nanotube film prepared in Example 1.

FIG. 6 is Raman spectra of the film made in Example 1, the spectra was obtained at five different sites of the same film.

FIG. 7 shows the transparency versus sheet resistance of the carbon nanotube film obtained in Examples 1 to 3 and the carbon nanotube film obtained by a conventional filtration method using Hipco sample, P3 sample and laser sample.

FIG. 8 is a Figure comparing the SEM image of the carbon nanotube film (FIG. 8(a)) of Example 2 under accelerating voltage of 15 kV with that of the carbon nanotube film (FIG. 8(b)) of Comparative Example 1.

### DETAILED DESCRIPTION

According to an embodiment, the present application will be described below with reference to the drawings. The carbon nanotube film can directly grow on a substrate through a CVD method, without using surfactant and/or membrane filter. Thereby, the process of the present application has eliminated the adverse effect on the nature of the films conventionally caused by surfactant and/or membrane filter.

In an embodiment, the present application provides a process of preparing a transparent conductive carbon nanotube film. The process includes:

preparing a uniform catalyst layer on a substate; and growing the transparent conductive carbon nanotube film on the uniform catalyst layer obtained by a chemical vapor deposition (CVD) method.

A uniform catalyst layer is essential for the direct growth of carbon nanotube films on a substrate, more specifically, a quasi 2-D single-walled carbon nanotube film with large area. As shown by the SEM image in the Examples, if the catalyst layer on the substrate is not uniform, the uniform carbon nanotube film cannot be obtained. This is verified by the conductivity of the substrate (quartz, for example) with carbon nanotube films. It is impossible to obtain a SEM image from the insulated quartz substrate under accelerating voltage of 15 kV if a uniform carbon nanotube film (i.e., conductive layer) is not present.

There is no particular limitation on the method to obtain a uniform catalyst layer in the present application. Any methods are applicable as long as a uniform catalyst layer can be obtained thereby.

For example, in one embodiment of the present application, the process for preparation includes formulating a catalyst solution using a solvent, forming a uniform catalyst solution film on a substrate, and drying the obtained uniform catalyst solution film, to form the uniform catalyst layer.

In an embodiment, a uniform catalyst layer can be obtained by formulating a catalyst into a solution by using a solvent, then forming a uniform catalyst solution layer, drying the catalyst solution layer, and finally forming a uniform catalyst layer.

There is no particular limitation on the substrate used in the process of the present application, and a commonly used substrate is applicable. In general, a transparent substrate is preferred, such as a quartz substrate, a silicon substrate and a glass substrate. In an embodiment, a quartz substrate and a silicon substrate are preferred, considering the temperature in the CVD method.

The catalyst layer obtained by applying the catalyst solution onto a substrate (e.g. quartz substrate) followed by air drying is not uniform. Although a carbon nanotube film can be formed from the catalyst layer, SEM image from the insulated quartz substrate under accelerating voltage of 15 kV cannot be obtained. That is, the carbon nanotube film is not conductive. Thus, the carbon nanotube film is produced not to be uniform. Although without wishing to be bound by theory, it is believed that, the catalyst solution layer obtained by applying the catalyst solution onto a substrate is not uniform, which may be caused by the flow limitation of the catalyst solution. Therefore, the term “uniform catalyst layer” as used herein means that the catalyst is distributed on the substrate uniformly so as to obtain continuous carbon nanotubes and a film, and a SME image at 15 kV can be obtained.

In order to obtain a uniform catalyst solution layer from the catalyst solution, and then a uniform catalyst layer, the following processes may be used in an embodiment: adding appropriate amount of the catalyst solution onto a substrate, then placing another substrate overlaid on the catalyst solution, clamping the substrate with clamps (as shown in FIG. 2) (Please note that the solution shall not flow out of the substrates, in order to avoid the growth of carbon nanotubes at undesired positions); drying for a period of time at vacuum and appropriate temperature; then taking out the substrates, and separating the two substrates. Thus, two substrates with a uniform catalyst layer are obtained. It should be appreciated that, when forming a uniform catalyst film by using above process, the amount of the catalyst solution depends on the size of the selected substrate to be used. The amount of solution shall be suitable for spreading over the surface of the substrate without flowing out of the substrates after the uplayer substrate has been overlaid and clamped. If the amount of the solution is too small, the solution will evaporate out before spreading completely. If the amount of the solution is too much, the solution will flood out of the substrates, and carbon nanotubes will grow at undesired positions. In principle, a small amount of solution may be used, since it ensures the solution from flowing out of the substrates. Meanwhile, the solution can spread over the surface of the substrates through immersional wetting and capillarity. Generally, as for the quartz substrate of 1.5 cm×3 cm, a catalyst solution of 5 microliter to 15 microliter, preferably 10 microliter, may be used.

As for the drying of the catalyst solution, it should be appreciated that the actual time and temperature in the drying step are relevant. Therefore, the drying time depends on the actual drying temperature. For example, the drying temperature may be 50° C. to 100° C., preferably, 60° C. to 80° C., while the drying time may be, for example, 30 minutes to 2 hours, such as 1 hour. For example, when quartz substrates of 1.5 cm×3 cm and catalyst solution of 10 microliter are used, the catalyst solution layer formed has a wet-film thickness of about 22 micron (10 microliter/(1.5 cm×3 cm)=22). In general, the wet-film thickness ranges from 11 micron to 33 micron according to an embodiment.

There is no particular limitation on the catalysts used in the present application, and any catalysts known for the growth of carbon nanotubes in CVD method can be used. In one embodiment, the catalysts may be selected from the group consisting of transition metals, salts of transition metals, and the combinations thereof. For example, in one embodiment of the present application, the catalysts includes iron salts, copper salts, cobalt salts, molybdenum salts or the combinations thereof. Iron salts, copper salts, cobalt salts, molybdenum salts or the combinations thereof which are commercially available can be used as the catalyst of the present application. In one preferred embodiment, the catalyst may be selected from the group consisting of FeCl₃, CuCl₂, and Co/Mo catalyst.

There is no particular limitation on the solvent for formulating the catalyst solution in the present application. However, it should be appreciated that, the specific solvent should be selected according to the specific catalyst. In one embodiment of the present application, alcohol based solvent, ether based solvent and ketone based solvent can be used. Preferably, the solvent may be selected from the group consisting of methanol, ethanol, acetone, diethyl ether and glycerol.

It has been found that, the concentration of the catalyst in the catalyst solution shall be selected in order to grow uniform carbon nanotube films. For example, the catalyst solution may have a concentration of 0.03 wt % to 2 wt %, preferably 0.05 wt % to 1 wt %, such as 0.1 wt %, when the catalyst is FeCl₃ or CuCl₂. The catalyst solution may have a concentration of 0.001 wt % to 2 wt %, preferably 0.01 to 1 wt %, such as 0.02 wt %, when the catalyst is Co/Mo catalyst. Within the above range of concentration, a uniform carbon nanotube film can be obtained according to an embodiment.

There is no particular limitation on the method used for formulating the catalyst solution in the present application. Appropriate stir may be adopted to formulate a catalyst solution. Ultrasonic dispersion may also be adopted to accelerate the dissolution of the catalyst in solvent.

For example, when FeC₃ and CuC₁ which are used as the catalyst to formulate the catalyst solution, commercial available ferric chloride and cupric chloride may be used, and appropriate solvent may be selected to formulate the catalyst solution. In an embodiment, the Co/Mo catalyst solution can be prepared by the method disclosed in Yoichi Murakami, et al., “Direct synthesis of high-quality single-walled carbon nanotubes on silicon and quartz substrates” (Chemical Physics Letters 377 (2003), 49-54), which is incorporated herein by reference.

The process of preparing Co/Mo catalyst solution is as follows: dissolving molybdenum acetate((CH₃COOH)₃Mo) and cobalt acetate((CH₃COOH)₂Co.4H2O) into an appropriate solvent (e.g. ethanol), in which the concentration of each metal is, for example, 0.01 wt %, respectively.

The CVD method is described as follows, according to an embodiment.

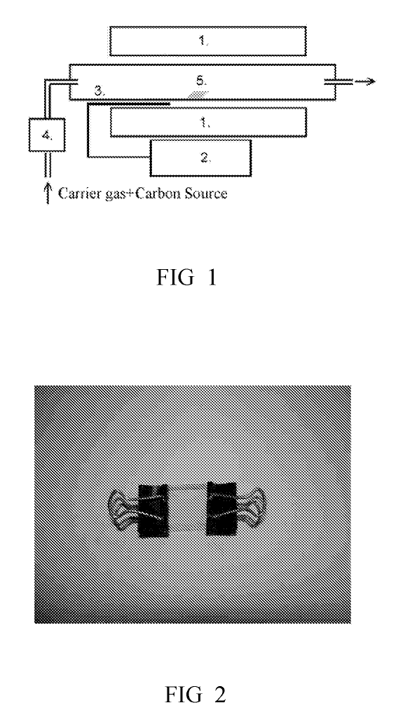

In the present application, conventional CVD system can be used for the growth of a transparent conductive carbon nanotube film on a uniform catalyst layer. For example, the CVD system shown in FIG. 1 can be used, which includes electric furnace 1, temperature controller 2, quartz tube 3, and flow meter 4. The substrate 5 can be placed in quartz tube 3.

In the present application, a transparent conductive carbon nanotube film can grow on the uniform catalyst layer by CVD method. In one embodiment, the CVD method includes reducing the catalyst in the catalyst layer. In an embodiment, the CVD method includes the growth of a transparent conductive carbon nanotube film by using a carbon source and a carrier gas.

In the present application, the general procedures of the CVD method used for the growth of a transparent conductive carbon nanotube film on a uniform catalyst layer are as follows:

In the CVD system, the quartz tube is horizontally placed in the electric furnace as a reaction chamber. A substrate 5 with a uniform catalyst layer is placed in the reaction chamber. The system is vacuumized to 10 Pa, then charged with argon. The procedures are repeated three times to ensure the inert gas atmosphere in the deposition system. Then, the central area of the system is heated to the activating (reducing) temperature. Hydrogen is charged into the system to activating (hydrogen reducing) the catalyst on the substrate for a suitable time. Then, under an appropriate reaction temperature, a carrier gas and a carbon source are allowed to flow into reaction chamber via a flow meter. After decompositing, diffusing and precipitating on the catalyst layer, the carbon source grows into carbon nanotubes, and then the carbon nanotube film is formed. Then, the electric furnace is shut off, and the inert gas is purged until the system falls to room temperature.

It is widely believed that, the variation of the free energy is almost zero when catalyst metal and carbon form carbide, i.e. the free energy changes little when carbon atom combines with or separates from such metal. Thus, during the growth of carbon nanotubes from the vapor phase, there is slight variation of the energy when the carbon atom in the catalyst particles precipitates from the catalyst particles, so that the basic dynamic conditions beneficial for the growth of carbon nanotubes from the vapor phase are provided (see, Zhang Ronghui, et al., “The Growing Mechanism of Vapor Grown Carbon Fibers Obtained on Catalysts”, Carbon, China Academic Journal Electronic Publishing House, No. 2, pp. 18-21, 1996). There is no particular limitation on the carbon source and the carrier gas used in the CVD method of the present application. For example, the carbon source may be hydrocarbon, such as methane. The carrier gas can generally be hydrogen.

In order to obtain a uniform carbon nanotube film, it is preferable to optimize the growing condition of the carbon nanotubes in the CVD method. In an embodiment, the activating (reducing) temperature in the CVD method is generally 600° C. to 1200° C., preferably 900 to 1000° C. In an embodiment, the reaction temperatures in the CVD method (e.g., the system temperature during the growth of the carbon nanotube films) are generally 600° C. to 1200° C., preferably 900° C. to 1000° C. Hydrogen is generally used to activate (reduce) the catalyst in the catalyst layer. The flow rate of the hydrogen for reducing catalyst is generally 20 sccm to 2000 sccm, preferably 100 sccm to 500 sccm, more preferably 200 sccm. The time used for reducing the catalyst with hydrogen ranged from 5 minutes to 200 minutes, preferably 10 to 40 minutes, more preferably 25 minutes. During the growth of the carbon nanotube films, the ratio of the flow rate of the carbon source to the flow rate of the carrier gas ranges from 1:8 to 3:4, preferably 1:4 to 1:2, more preferably 3:8, according to an embodiment.

The term “carbon nanotubes” includes a variety of different and suitable carbon nanotube materials, for example, single-walled carbon nanotubes and multi-walled carbon nanotubes, and the combination thereof, according to the number of the carbon atom layers forming the tube wall. The term “carbon nanotubes” also includes, for example, metallic carbon nanotubes and semiconductive carbon nanotubes, and the combination thereof, according to electrical property.

Preferably, the carbon nanotube film prepared in an embodiment is single-walled carbon nanotubes film. The single-walled carbon nanotubes include metallic single-walled carbon nanotubes(M-SWNT), semiconductive single-walled carbon nanotubes(S-SWNT), and the combination thereof.

According to an embodiment, a carbon nanotube film can directly grow on a substrate, without using any surfactant and membrane filter. Thus, there is no need to remove the surfactant and the membrane filter. Moreover, the carbon nanotube film prepared by the present process may have a transparency of up to >99%, and a sheet resistance of down to ≦10000Ω/□, since the impact of the membrane filter and the surfactant on sheet resistance and transparency is eliminated. This contrasts the conventional filtration method in which such high transparency and such low sheet resistance cannot be obtained.

In another embodiment, the present application provides a carbon nanotube film obtained by the process as previously described.

The carbon nanotube film has higher transparency and much lower sheet resistance compared with the carbon nanotube film obtained by a conventional filtration process.

Thus, the carbon nanotube film according to an embodiment display superior properties as compared to conventional CNT film.

In a forth embodiment, the present application provides a carbon nanotube element including CNT films as previously described.

For example, the carbon nanotube element is selected from the group consisting of a CNT conductive film, a field emission source, a transistor, a conductive wire, a nano-electro-mechanic system(NEMS), a spin conduction device, a nano cantilever, a quantum computing device, a lighting emitting diode, a solar cell, a surface-conduction electron-emitter display, a filter, a drug delivery system, a thermal conductive material, a nano nozzle, an energy storage system, a space elevator, a fuel cell, a sensor and a catalyst carrier.

According to an embodiment, the carbon nanotubes is preferably single-walled carbon nanotubes.

### EXAMPLES

The present application will now be further described with reference to a number of specific examples. The raw materials and reactants used in the present application are commercially available or can be obtained by the conventional techniques of the art, unless the context clearly dictates otherwise.

The main raw materials are as follows:

CuCl₂.2H₂O, available from Jinke Institute of Finechemicals, Tianjin, analytically pure;

FeCl₃, available from Sinopharm Chemical Reagent Co., Ltd, chemically pure;

Molybdenum acetate ((CH₃COOH)₂Mo) and cobalt acetate ((CH₃COOH)₂Co.4H₂O) are available from Wako Pure Chemical Industries, Ltd; Ethanol, available from Beijing Chemical Works, analytically pure;

HiPCO carbon nanotubes, available from Carbon Nanotechnology Inc.;

P3 carbon nanotubes (arc discharge nanotube), available from Carbon Solutions Inc.;

Laser carbon nanotubes (L-CNTs), are synthesized according to the known methods (see, for example, Thess, A., et al., Science, vol. 273, page 483, 1996; and Shiraishi, M. et al., Chemical Physics Letters, vol. 358, page 213, 2002). Briefly, L-CNTs are synthesized using a Ni/Co catalyst by laser ablation at 1200° C. and purified using H₂O₂, HCl and NaOH solutions and heated at 650° C. at a pressure of 0.01 Pa for 1 h.

Characterization

The carbon nanotube film can be characterized as follows:

Raman spectroscopy data are obtained with LabRAM HR-800 Raman Spectrometric Analyzer;

Scanning electron microscope (SEM) data are obtained with Hitachi S-4300F;

AFM images are obtained with Multimode Nanoscope controller (Veeco Inc.), with tapping module as the work module.

The sheet resistance of the carbon nanotube film is measured with 4-probe Loresta-EP MCP-T360.

The transparency of the carbon nanotube film is measured with UV-vis-NIR spectrophotometer (JASCO V-570).

Raman spectroscopy is one of the useful methods to detect carbon nanotubes, which not only shows the regularity and purity of the sample, but also defines the diameter distribution of carbon nanotubes. A well grown carbon nanotubes film can be directly tested by Raman spectroscopy.

In the Raman spectra, there are three peaks or regions concerned: the radial breathing modes (RBM) (about 100-300 cm⁻¹), D band (to 1350 cm⁻¹), and G band (to 1570 cm⁻¹) (see M. S. Dresselhaus, et al., Raman Spectroscopy of Carbon Nanotubes in 1997 and 2007, J. Phys. Chem. C, 111(48), 2007, 17887-17893). The RMB peaks are the characteristic peaks of carbon nanotubes, and are special for single-walled carbon nanotubes, corresponding with the diameters of carbon nanotubes. From the RBM peaks, the distribution of carbon nanotubes diameters can be seen. According to the relation (see Araujo, P. T., et al., Third and fourth optical transitions in semiconducting carbon nanotubes. Phys. Rev. Lett., 98, 2007, 067401.) ω_{RBM}=A/dₜ+B, with A=217.8±0.3 cm⁻¹ nm and B=15.7±0.3 cm⁻¹, where ω_{RBM} refers to the wave number at the RBM peak in cm⁻¹, and dₜ refers to the diameter of carbon nanotubes in nm, we can infer the diameter distribution of the as-prepared carbon nanotubes. The D band and G band are corresponding to amorphous carbon and graphitic carbon, respectively. The purity of carbon nanotubes can be estimates according to the intensity ratio of G band and D band (G/D). The larger G/D is, and the more graphitic carbon are. The less impurities or defects are, the purity is higher.

### Example 1

Step 1. A uniform catalyst layer was prepared by Co/Mo catalyst according to the following procedures:

Molybdenum acetate ((CH₃COOH)₂Mo) and cobalt acetate ((CH₃COOH)₂Co.4H₂O) were dissolved into ethanol, with the concentration of each metal (Mo and Co) as 0.01 wt %, and the catalyst solution was obtained. Then, 10 microliter catalyst solution was dropped onto a quartz plate. Another quartz plate was overlaid on the catalyst solution, and then the quartz plates were clamped. As shown in FIG. 2, there was no solution flooding out of the substrates. After that, the substrates were dried in a vacuum oven at 70° C. for 2 hours, the quartz plates were taken out, and separated. Thereby, two quartz plates with catalyst layer were obtained.

Step 2. A carbon nanotube film grew on above prepared catalyst layer:

The quartz plate with a uniform catalyst layer was placed in the CVD system shown in FIG. 1. The system was vacuumized to 10 Pa, then charged with argon. The procedures are repeated three times to ensure the inert gas atmosphere in the deposition system. Then, the central area of the CVD system was heated to 900° C. Hydrogen(200 sccm) was charged into the CVD system, and reducing was conducted for 20 minutes. The temperature was elevated to 970° C. Hydrogen(32 sccm) and methane(12 sccm) were charged in, and reacted for 30 minute. Finally, the electric furnace was shut off, and the inert gas was purged until the temperature of the system fell to room temperature.

### Example 2

A carbon nanotube film was prepared according to the procedure of Example 1, except that the catalyst solution was obtained in step 1 as follows: the solution of FeCl₃ in ethanol was formulated as the catalyst solution, with the concentration of Fe being 0.1 wt %.

### Example 3

A carbon nanotube film was prepared according to the procedure of Example 1, except that the catalyst solution was obtained in step 1 as follows: the solution of CuCl₂.2H₂O in ethanol was formulated as the catalyst solution, with the concentration of Cu being 0.1 wt %.

### Comparative Example 1

A carbon nanotube film was prepared according to the procedure of Example 1, except that the catalyst layer was obtained in step 1 as follows: 0.1 wt % solution of FeCl3 in ethanol was formulated as the catalyst solution. And then, 10 microliter of the catalyst solution was dropped onto a quartz plate, and dried in air at room temperature, so as to obtain a quartz plate with a catalyst layer.

The carbon nanotube film obtained in Example 1 was measured by SEM, and the results were shown in FIG. 3, wherein the amplification factors in FIGS. 3(a), (b) and (c) was 2000, 8000 and 18000, respectively. It can be seen from FIG. 3(a) that, the carbon nanotube film prepared in Example 1 is very even and uniform with large area. It can be seen from FIG. 3(b) that, there are few tips of carbon nanotubes on this image (the size of this image is about 10 micron×20 micron), which suggests that most of the carbon nanotubes in this film is longer than 20 micron. Neither amorphous carbon nor catalyst particles can be seen in FIG. 3(c), indicating that the carbon nanotubes in the film are very pure. Almost no amorphous carbon is generated during the synthesis process, and almost every catalyst particles are served as the active tips for carbon nanotube synthesis and finally become part of the carbon nanotubes.

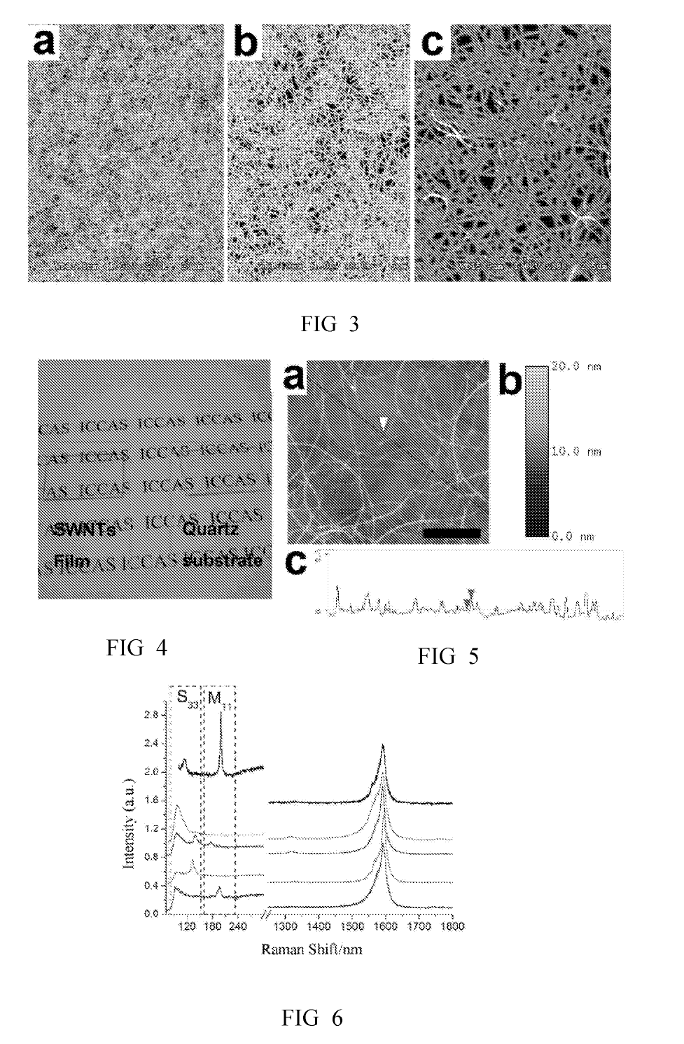

A quartz plate with carbon nanotube films obtained in Example 1 was placed on a substrate with the wording “ICCAS”. Meanwhile, a quartz plate (without carbon nanotube films) identical to the one used to prepare the quartz plate with carbon nanotube film was placed side by side. The substrate with two quartz plates was photographed by SONY cyber-shot. The obtained image is shown in FIG. 4. It can be seen from FIG. 4 that, the transparency of the carbon nanotube film is very high. The transparency of the quartz plate with carbon nanotube film and the same quartz plate without carbon nanotube film are basically the same.

A AFM test on the carbon nanotube film obtained in Example 1 is conducted. The results obtained are shown in FIG. 5, wherein, FIG. 5(a) is a whole AFM image; FIG. 5(b) shows the altitude scale in the image; and FIG. 5(c) is a digitized altigraph corresponding to each carbon nanotube shown in FIG. 5(a). It can be seen from FIG. 5 that, most of the carbon nanotubes are individual with the diameters between 1.2 nm and 2.4 nm. For example, in FIG. 5(a), the height of the position marked by a triangle icon is 1.85 nm, indicating that the carbon nanotube at this position has a diameter of 1.85 nm. Some carbon nanotubes bundles also can be seen in FIG. 5. However, most of said carbon nanotubes bundles have a height less than 5 nm. The black bar in FIG. 5(a) represents 500 nm.

To confirm the evenness of the carbon nanotubes prepared in Examples, the points of the film prepared in Example 1 were tested randomly by Raman spectra with the spot size of the excitation laser of 1 micron. It is found that, the Raman signals can be obtained at every point of said film. FIG. 6 shows the Raman signals of 5 points randomly selected from the carbon nanotube film of Example 1. Since the spot size of the excitation laser is only 1 micron, it can be seen that the carbon nanotube film of Example 1 is nearly single layer, and only several carbon nanotubes show their Raman signals at one point. It can be seen from the RBM region of FIG. 6 that, most of the carbon nanotubes are individual, and the carbon nanotubes are the mixture of semiconducting carbon nanotubes and metallic carbon nanotubes with the diameter between 1.2 and 2.3 nm. It can also be seen from the RBM region of FIG. 6 that the carbon nanotube prepared by the present application is single-walled carbon nanotube. The D bands of the film are either very small (see FIG. 6, the second plot and the third plot from the top to the bottom of the Figure) or almost disappeared (see FIG. 6, the other plots, i.e., the first plot, the fourth plot and the fifth plot from the top to the bottom of the Figure).

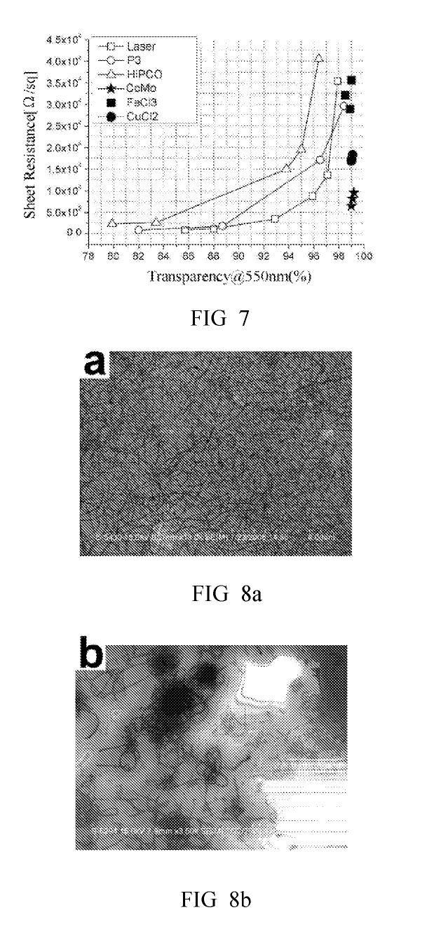

FIG. 7 compares the relationships between the transparency and the sheet resistance of the carbon nanotube film obtained in Examples 1, 2, and 3. FIG. 7 also shows the transparency versus sheet resistance plot of the films prepared by a conventional filtration method by using HiPCO nanotubes, P3 carbon nanotubes and laser carbon nanotubes.

As for the conventional process of preparing carbon nanotube films by a filtration method, the method reported by Wu, et al. (see, Wu, Z. C.; Chen, Z. H.; Du, X.; Logan, J. M.; Sippel, J.; Nikolou, M.; Kamaras, K.; Reynolds, J. R.; Tanner, D. B.; Hebard, A. F.; Rinzler, A. G. Science 2004, 305, 1273) was used to prepare the carbon nanotube film.

It can be seen from FIG. 7 that, it is difficult to fabricate carbon nanotube films with the transparency above 99% by the conventional process based on a filtration method. The sheet resistance of the films prepared from HiPCO nanotube, P3 carbon nanotubes and laser carbon nanotubes based on a filtration method all exceeds 28000Ω/□ when the transparency is above 98%.

The transparency and conductivity of the carbon nanotube film prepared by the present application are both improved, as compared with the carbon nanotube film prepared by a conventional process. The transparency of the carbon nanotube films of examples 1-3 is greater than 99%. The average sheet resistance of the films of examples 1-3 is shown in table 1. It can be seen from table 1 that, the average sheet resistance of Example 1 is down to 8056Ω/□, much lower than that of the films prepared by a conventional filtration method. Furthermore, it also can be seen from table 1 that, the conductivity of the films prepared from CuCl₂ as catalyst is superior to that of the films prepared from FeCl₃ as catalyst.

TABLE 1
The average sheet resistance of the carbon nanotube film
of examples 1-3

| | Average sheet resistance, Ω/□ |
|---|---|
| Example 1 | 8056 |
| Example 2 | 32200 |
| Example 3 | 17466 |

FIG. 8 compares the SEM image of the carbon nanotube film of Example 2 under accelerating voltage of 15 kV with that of the carbon nanotube film of Comparative Example 1 under the same condition. FIG. 8(a) shows the SEM image of the carbon nanotube film of Example 2 under accelerating voltage of 15 kV. The image of FIG. 8(a) is clear and stable, wherein all carbon nanotubes distribute continuously, indicating a uniform, conductive, and continuous carbon nanotube film. FIG. 8(b) shows the SEM image of the carbon nanotube film of Comparative Example 1 under accelerating voltage of 15 kV. It can be seen from FIG. 8(b) that, the carbon nanotubes are discrete, indicating that the carbon nanotube film is not uniform and continuous. In such a case, because the quartz substrate is nonconducting, and the carbon nanotubes can't form electric path due to the uncontinuity, a clear SEM image can't be obtained due to part or all of the region brighten up quickly under instant accumulation of charge. This is the typical behavior of the SEM image of the nonconducting substrate.

Although the present application has been explained based on some theories provided herein, it should be appreciated that the present application is not intended to be limited by these theories. For example, additional process procedures may include drying, washing and so on, as long as there is no adverse impacts on the effects of the present application.

The terms “Optional' and “optionally” as used herein mean that the subsequent event or circumstance (such as treatment steps) may or may not occur, and that the description includes instances where the event occurs and instances where it does not.

All the references cited are incorporated by reference into the present description.

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

1. A process of preparing a transparent conductive carbon nanotube film, the process comprising:
preparing a uniform catalyst layer on a substate; and
growing the transparent conductive carbon nanotube film on the uniform catalyst layer by chemical vapor deposition.

2. The process of claim 1, wherein preparing the uniform catalyst layer includes:
formulating a catalyst solution by using a solvent,
forming an uniform catalyst solution film on a substrate by using the catalyst solution, and
drying the obtained uniform catalyst solution film to form the uniform catalyst layer.

3. The process of claim 1, wherein the catalyst is selected from the group consisting of transition metals, salts of transition metals, and combinations thereof.

4. The process of claim 1, wherein the catalyst is selected from the group consisting of iron salts, copper salts, cobalt salts, molybdenum salts, and combinations thereof.

5. The process of claim 4, wherein the catalyst is selected from the group consisting of FeCl₃, CuCl₂, and Co/Mo catalyst.

6. The process of claim 2, wherein the catalyst solution has a concentration ranging from 0.03 wt % to 2 wt %, when the catalyst is FeCl₃ or CuCl₂, and the catalyst solution has a concentration ranging from 0.001 wt % to 2 wt %, when the catalyst is Co/Mo catalyst.

7. The process of claim 1, wherein chemical vapor deposition includes reducing the catalyst in the catalyst layer.

8. The process of claim 7, wherein chemical vapor deposition further comprises growing the transparent conductive carbon nanotube film by using a carbon source and a carrier gas.

9. The process of claim 1, wherein the transparent conductive carbon nanotube film grows during chemical vapor deposition at a temperature ranging from 600° C. to 1200° C.

10. The process of claim 7, wherein the catalyst is reduced at a temperature ranging from 600° C. to 1200° C.

11. The process of claim 7, wherein the catalyst is reduced by using hydrogen at 20 sccm to 2000 sccm.

12. The process of claim 7, wherein the catalyst is reduced for 5 minutes to 200 minutes.

13. The process of claim 8, wherein the ratio of the flow rate of the carbon source to the flow rate of the carrier gas ranges from 1:8 to 3:4.

14. The process of claim 2, wherein the solvent is selected from the group consisting of alcohol based solvent, ether based solvent and ketone based solvent.

15. The process of claim 2, wherein the solvent is selected from the group consisting of methanol, ethanol, acetone, diethyl ether and glycerol.

16. The process of claim 2, wherein the uniform catalyst solution film has a wet-film thickness ranging from 11 micron to 33 micron.

17. The process of claim 1, wherein the carbon nanotube film is a single-walled carbon nanotube film.

18. A carbon nanotube element, comprising a carbon nanotube film obtained by preparing a transparent conductive carbon nanotube film by preparing a uniform catalyst layer on a substate; and growing the transparent conductive carbon nanotube film on the uniform catalyst layer by chemical vapor deposition.

19. The carbon nanotube element of claim 18, wherein the carbon nanotube element is selected from the group consisting of a conductive film of carbon nanotubes, a field emission source, a transistor, a conductive wire, a nano-electro-mechanic system, a spin conduction device, a nano cantilever, a quantum computing device, a lighting emitting diode, a solar cell, a surface-conduction electron-emitter display, a filter, a drug delivery system, a thermal conductive material, a nano nozzle, an energy storage system, a space elevator, a fuel cell, a sensor, and a catalyst carrier.
